(19) United States
(12) Patent Application Publication
(10) Pub. No.: US 2011/0140781 A1
(43) Pub. Date: Jun. 16, 2011

(54) IMPEDANCE MATCHING CIRCUIT ELIMINATING INTERFERENCE BETWEEN SIGNAL LINES AND POWER AMPLIFIER HAVING THE SAME

(75) Inventors: Youn Suk KIM, Gyunggi-do (KR); Shinichi IIZUKA, Gyunggi-do (KR); Hyo Gun BAE, Seoul (KR); Sang Hee KIM, Seoul (KR); Ki Joong KIM, Gyunggi-do (KR)

(73) Assignee: SAMSUNG ELECTRO-MECHANICS CO., LTD., Gyunggi-do (KR)

(21) Appl. No.: 12/826,098

(22) Filed: Jun. 29, 2010

(30) Foreign Application Priority Data
Dec. 10, 2009 (KR) 10-2009-0122191

(51) Int. Cl. H03F 1/08; H03H 7/38

(52) U.S. Cl. 330/195; 333/32

(57) ABSTRACT

Disclosed are an impedance matching circuit preventing the occurrence of inter-line interference by making currents at adjacent lines flow in the same direction, and a power amplifier having the same. The impedance matching circuit eliminating interference between signal lines includes: a first transformer including a first input line which forms a first loop by a conductor receiving a signal and a first output line which forms a second loop by a conductor outputting a signal at the inner side of the first loop of the first input line to match the impedance of a path of an input signal; and a second transformer including a second input line which forms a third loop by a conductor receiving a signal and a second output line which forms a fourth loop by a conductor outputting a signal at the inner side of the third loop of the second input line to match impedance, wherein the direction of current in the first input line of the first transformer and the direction of current in the second input line of the second transformer are the opposite so that a portion of the first input line of the first transformer and a portion of the second input line of the second transformer adjacent to the portion of the first input line of the first transformer have the same current direction.

### CROSS-REFERENCE TO RELATED APPLICATIONS

This application claims the priority of Korean Patent Application No. 10-2009-0122191 filed on Dec. 10, 2009, in the Korean Intellectual Property Office, the disclosure of which is incorporated herein by reference.

### BACKGROUND OF THE INVENTION

1. Field of the Invention

The present invention relates to an impedance matching circuit and a power amplifier having the same and, more particularly, to an impedance matching circuit capable of preventing the occurrence of interference between signal lines by making currents in adjacent signal lines flow in the same direction.

2. Description of the Related Art

Recently, mobile communication terminals have been widely used thanks to the convenience of their use. As users increasingly use mobile terminals, they prefer using mobile communication terminals for longer periods of time, as well as driving multiple applications to their satisfaction.

In all probability, it will be important to increase battery capacity in order to lengthen the usage time of mobile communication terminals, but an increase in battery size faces a restriction in the market situation in which mobile communication terminals are required to be lighter, thinner, shorter, and smaller. Thus, the power efficiency of primary elements within mobile communication terminals needs to be increased.

Meanwhile, mobile communication terminals employ a power amplifier in order to transmit and receive radio signals, and the power amplifier makes up a significant portion of the overall power consumption of mobile communication terminals.

The power amplifier employs an impedance matching circuit in order to match the impedance of input and output elements. In this respect, in order to reduce the size of the elements, an amplifying element and an impedance matching circuit are integrated on a single substrate in a CMOS process, so signal lines of the impedance matching circuit may possibly interfere with each other.

Then, a transmission efficiency of the signal lines in the impedance matching circuit is degraded, resulting in an increase in power consumption.

### SUMMARY OF THE INVENTION

An aspect of the present invention provides an impedance matching circuit capable of preventing the occurrence of interference between signal lines by making currents in adjacent lines flow in the same direction, and a power amplifier having the same.

According to an aspect of the present invention, there is provided an impedance matching circuit eliminating interference between signal lines, including: a first transformer including a first input line which forms a first loop by a conductor of a certain length having one end and the other end receiving a signal, and a first output line which forms a second loop by a conductor of a certain length having one end and the other end outputting a signal at the inner side of the first loop of the first input line to match the impedance of a path of an input signal according to its electromagnetic reaction with the first input line; and a second transformer including a second input line which forms a third loop by a conductor of a certain length having one end and the other end receiving a signal, and a second output line which forms a fourth loop by a conductor of a certain length having one end and the other end outputting a signal at the inner side of the third loop of the second input line to match the impedance of a path of an input signal according to its electromagnetic reaction with the second input line, wherein the direction of current in the first input line of the first transformer and the direction of current in the second input line of the second transformer are the opposite, so that a portion of the first input line of the first transformer and a portion of the second input line of the second transformer adjacent to the portion of the first input line of the first transformer have the same current direction.

A plurality of first and second transformers may be provided, and in this case, the plurality of first transformers may be disposed in a row, and the plurality of second transformers may be disposed between the first transformers.

A balanced signal may be input to each of the first and second transformers.

According to another aspect of the present invention, there is provided a power amplifier having an impedance matching circuit eliminating interference between signal lines, including: an amplifying unit amplifying an input signal; and an impedance matching unit including a first transformer including a first input line which forms a first loop by a conductor of a certain length having one end and the other end receiving a signal which has been amplified by the amplifying unit and a first output line which forms a second loop by a conductor of a certain length having one end and the other end outputting a signal at the inner side of the first loop of the first input line to match the impedance of a path of an input signal according to its electromagnetic reaction with the first input line, and a second transformer including a second input line which forms a third loop by a conductor of a certain length having one end and the other end receiving a signal which has been amplified by the amplifying unit and a second output line which forms a fourth loop by a conductor of a certain length having one end and the other end outputting a signal at the inner side of the third loop of the second input line to match the impedance of a path of an input signal according to its electromagnetic reaction with the second input line, wherein the direction of current in the first input line of the first transformer and the direction of current in the second input line of the second transformer are the opposite so that a portion of the first input line of the first transformer and a portion of the second input line of the second transformer adjacent to the portion of the first input line of the first transformer have the same current direction.

A plurality of first and second transformers may be provided, and in this case, the plurality of first transformers may be disposed in a row, and the plurality of second transformers may be disposed between the first transformers.

A balanced signal may be input to the amplifying unit.

The amplifying unit may include first and second input amplifying unit formed to correspond in a one-to-one manner to the first and second transformers and providing an amplified signal.

The amplifying unit may include a plurality of input amplifying units, and the plurality of input amplifying units are formed to correspond in a one-to-one manner to the plurality of first and second transformers and providing an amplified signal.

According to another aspect of the present invention, there is provided a power amplifier having an impedance matching circuit eliminating interference between signal lines, including: an impedance matching unit including a first transformer including a first input line which forms a first loop by a conductor of a certain length having one end and the other end receiving a signal and a first output line which forms a second loop by a conductor of a certain length having one end and the other end outputting a signal at the inner side of the first loop of the first input line to match the impedance of a path of an input signal according to its electromagnetic reaction with the first input line, and a second transformer including a second input line which forms a third loop by a conductor of a certain length having one end and the other end receiving a signal and a second output line which forms a fourth loop by a conductor having one end and the other end outputting a signal at the inner side of the third loop of the second input line to match the impedance of a path of an input signal according to its electromagnetic reaction with the second input line, wherein the direction of current in the first input line of the first transformer and the direction of current in the second input line of the second transformer are the opposite so that a portion of the first input line of the first transformer and a portion of the second input line of the second transformer adjacent to the portion of the first input line of the first transformer have the same current direction; and an amplifying unit amplifying a signal outputted from the impedance matching unit.

A plurality of first and second transformers may be provided, and in this case, the plurality of first transformers may be disposed in a row, and the plurality of second transformers may be disposed between the first transformers.

A balanced signal may be input to each of the first and second transformers.

The amplifying unit may include at least first and second output amplifying units formed to correspond in a one-to-one manner to the first and second transformers and amplifying signals from the first and second output lines with a pre-set gain.

The amplifying unit may include a plurality of output amplifying units, and the plurality of output amplifying units may be formed to correspond in a one-to-one manner to the plurality of first and second transformers and amplifying an output signal with a pre-set gain.

According to another aspect of the present invention, there is provided a power amplifier having an impedance matching circuit eliminating interference between signal lines, including: a first amplifying unit amplifying an input signal; an impedance matching unit including a first transformer including a first input line which forms a first loop by a conductor of a certain length having one end and the other end receiving a signal which has been amplified by the first amplifying unit and a first output line which forms a second loop by a conductor of a certain length having one end and the other end outputting a signal at the inner side of the first loop of the first input line to match the impedance of a path of an input signal according to its electromagnetic reaction with the first input line, and a second transformer including a second input line which forms a third loop by a conductor of a certain length having one end and the other end receiving a signal which has been amplified by the first amplifying unit and a second output line which forms a fourth loop by a conductor of a certain length having one end and the other end outputting a signal at the inner side of the third loop of the second input line to match the impedance of a path of an input signal according to its electromagnetic reaction with the second input line, wherein the direction of current in the first input line of the first transformer and the direction of current in the second input line of the second transformer are the opposite, so that a portion of the first input line of the first transformer and a portion of the second input line of the second transformer adjacent to the portion of the first input line of the first transformer have the same current direction; and a second amplifying unit re-amplifying a signal output from the impedance matching unit.

A plurality of first and second transformers may be provided, and in this case, the plurality of first transformers may be disposed in a row, and the plurality of second transformers may be disposed between the first transformers.

A balanced signal may be input to the first amplifying unit.

The first amplifying unit may include at least first and second input amplifying units formed to correspond in a one-to-one manner to the first and second transformers and providing an amplified signal.

The first amplifying units may include a plurality of input amplifying units, and the plurality of input amplifying units may be formed to correspond in a one-to-one manner to the plurality of first and second transformers and providing an amplified signal.

The second amplifying unit may include a plurality of first and second output amplifying units formed to correspond in a one-to-one manner to the first and second transformers and amplifying signals from the first and second output lines with a pre-set gain.

The amplifying unit may include a plurality of output amplifying units, and the plurality of output amplifying units may be formed to correspond in a one-to-one manner to the plurality of first and second transformers and re-amplifying an output signal with a pre-set gain.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 illustrates the configuration of an impedance matching circuit according to an exemplary embodiment of the present invention;

FIG. 2 illustrates the configuration an impedance matching circuit according to another exemplary embodiment of the present invention;

FIG. 3 illustrates the configuration of a power amplifier according to an exemplary embodiment of the present invention; and

FIG. 4 illustrates the configuration of a power amplifier according to another exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

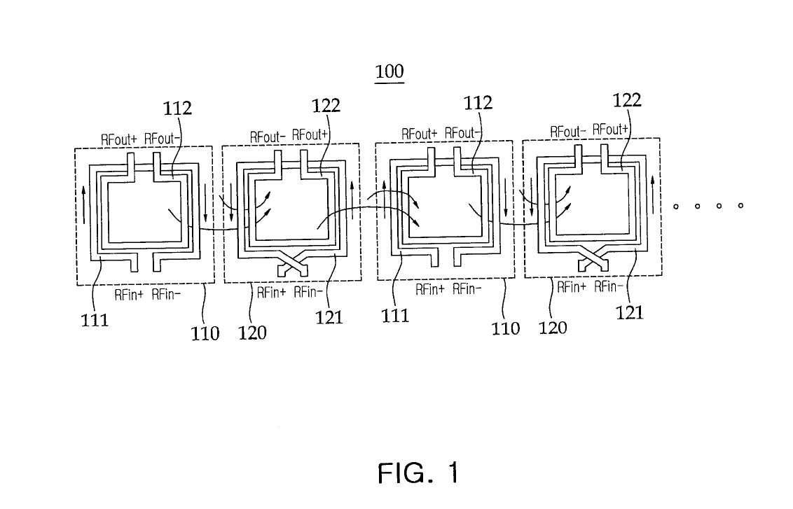

FIG. 1 illustrates the configuration of an impedance matching circuit according to an exemplary embodiment of the present invention.

With reference to FIG. 1, an impedance matching circuit 100 according to an exemplary embodiment of the present invention may include first and second transformers 110 and 120.

The first and second transformers 110 and 120 may include input lines 111 and 121 that receive a signal, respectively, and output lines 112 and 122 that are electromagnetically coupled with the input lines 111 and 121 to output a signal, respectively.

The first input line 111 of the first transformer 110 is configured such that a conductor of a certain length having one end and the other end receiving a signal forms a first loop, and the first output line 112 of the first transformer 110 may be configured such that a conductor of a certain length having one end and the other end outputting a signal forms a second loop at the inner side of the first loop of the first input line 111.

The second input line 121 of the second transformer 120 is configured such that a conductor of a certain length having one end and the other end receiving a signal forms a first loop, and the second output line 122 of the second transformer 120 may be configured such that a conductor of a certain length having one end and the other end outputting a signal forms a second loop at the inner side of the first loop of the first input line 121.

In this case, the direction in which a signal is input to the first input line 111 of the first transformer 110 and the direction in which a signal is input to the second input line 121 of the second transformer 120 are different, making the current directions contrary to each other.

Namely, when a signal is input according to Fleming's right hand rule in which a magnetic field is generated to rotate based on a current proceeding direction as an axis, current flows in the first input line 111 of the first transformer 110 and the second input line 121 of the second transformer 120.

At this time, the signal input directions are made to be opposite to each other. Namely, current flows along the loop from left to right at the first input line 111 of the first transformer 110, and current flows along the loop from right to left at the second input line 121 of the second transformer 120. To this end, one end and the other end of the second input line 121 of the second transformer 120 cross each other, and a signal of a plus level (RFin+) among balanced signals is input to one end of the second input line 121, and a signal of a minus level (RFin−) among the balanced signals is input to the other end of the second input line 121.

Accordingly, the current directions at mutually adjacent portions of the first input line 111 of the first transformer 110 and the second input line 121 of the second transformer 120 are the same, and accordingly, a magnetic field is not canceled out but compensated for as indicated by arrows.

As illustrated, a plurality of first transformers 110 and a plurality of second transformers 120 may be formed. When the plurality of first transformers 110 are provided, the plurality of second transformers 120 may be disposed between the first transformers 110.

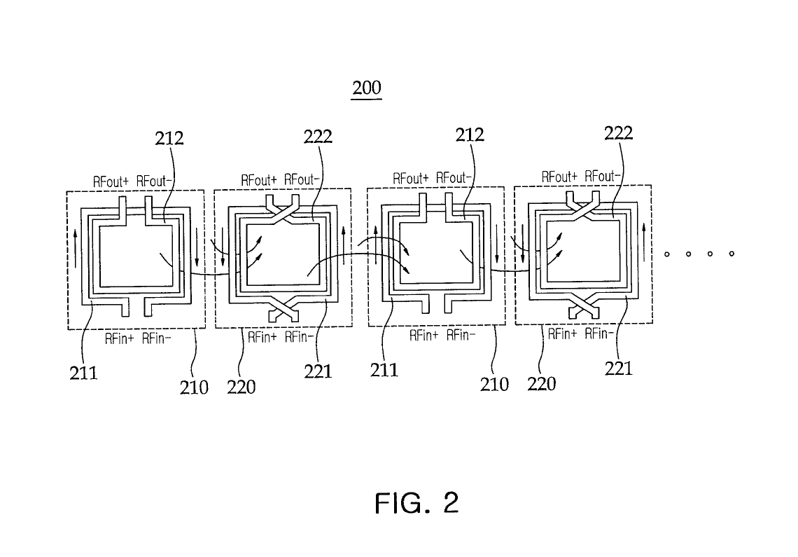

FIG. 2 illustrates the configuration an impedance matching circuit according to another exemplary embodiment of the present invention.

With reference to FIG. 2, an impedance matching circuit 200 according to another exemplary embodiment of the present invention is similar to the impedance matching circuit illustrated in FIG. 1. Thus, a detailed description of a first input line 211 and a first output line 212 of a first transformer 210 and a second input line 221 of a second transformer 220 will be omitted.

According to the present exemplary embodiment, a second output line 222 of the second transformer 220 may be formed such that a current direction is contrary to the second output line 212 of the first transformer 220 like the second input line 221.

Namely, one end and the other end of the second output line 222 cross each other, so a signal of a plus level (RFin+), among balanced signals, is input to one end of the second output line 222 and a signal of a minus level (RFin−), among the balanced signals, is input to the other end of the second output line 222.

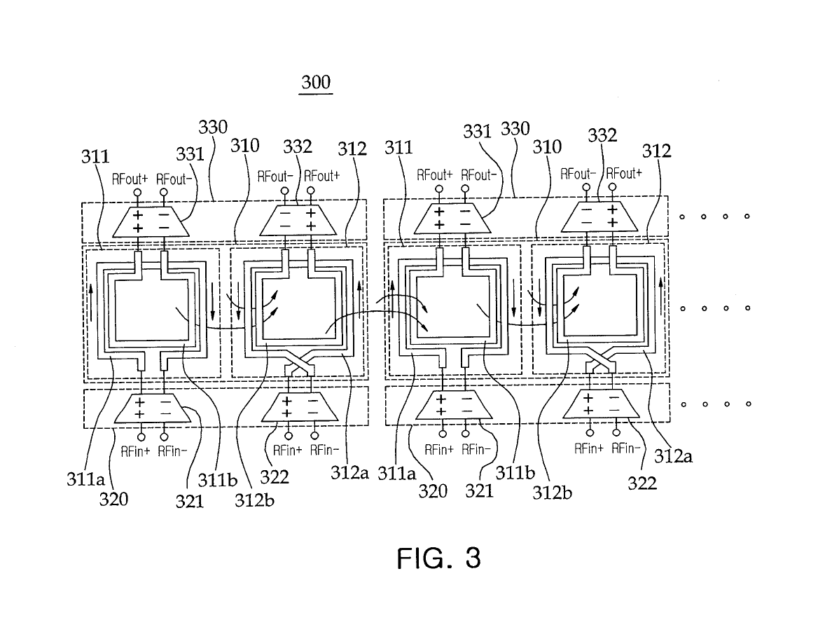

FIG. 3 illustrates the configuration of a power amplifier according to an exemplary embodiment of the present invention.

With reference to FIG. 3, a power amplifier according to an exemplary embodiment of the present invention may include a first amplifying unit 320, an impedance matching unit 310, and a second amplifying unit 330.

The first amplifying unit 320 may include a plurality of first and second input amplifying units 321 and 322. The plurality of first and second input amplifying units 321 and 322 may correspond to the plurality of first and second transformers 311 and 312 in a one-to-one manner and may be electrically connected therewith, respectively.

The first and second input amplifying units 321 and 322 amplify input signals RFin+ and RFin− with a pre-set gain and transfer the amplified signals to the corresponding transformers 311 and 312, respectively, for impedance matching.

The impedance matching unit 310 may include the plurality of first and second transformers 311 and 312.

As shown in FIG. 1, the first and second transformers 311 and 312 may have first and second input lines 311a and 312a and first and second output lines 311b and 312b, respectively. The first and second input lines 311a and 312a receive the amplified signals from the corresponding input amplifying units 321 and 322, respectively, and the first and second output lines 311b and 312b of the first and second transformers 311 and 312 may be electromagnetically coupled with the first and second input lines 311a and 312a to match the impedance of the paths of the transferred signals. The configuration and operation of the first and second input lines are the same as those illustrated in FIG. 1, so a detailed description thereof will be omitted.

The second amplifying unit 330 may include a plurality of first and second output amplifying units 331 and 332.

The plurality of first and second output amplifying units 331 and 332 may correspond to the plurality of first and second transformers 311 and 312 in a one-to-one manner and may be electrically connected therewith, respectively.

The first and second output amplifying units 331 and 332 may amplify the impedance-matched signals transferred from the corresponding transformers with a pre-set gain and output the amplified signals (RFout+, RFout−). In this case, the polarity of the signal output from the second output line 312b of the second transformer 312 is the opposite to that of the signal output from the first output line 311b of the first transformer 311, so the polarity of the signal output from the second output amplifying unit 332 is the opposite to that of the signal output from the first output amplifying unit 331.

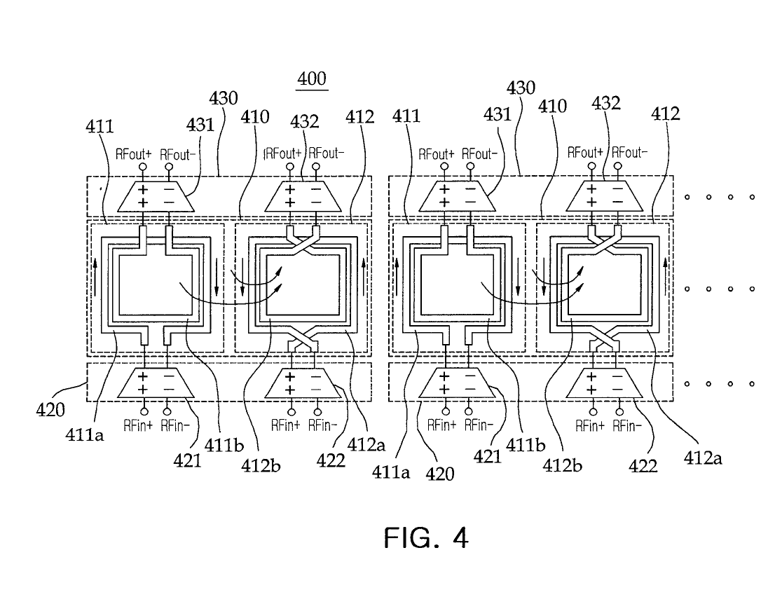

FIG. 4 illustrates the configuration of a power amplifier according to another exemplary embodiment of the present invention.

With reference to FIG. 4, a power amplifier 400 according to another exemplary embodiment of the present invention may include a first amplifying unit 420, an impedance matching unit 410, and a second amplifying unit 430.

The first amplifying unit 420 may include a plurality of first and second input amplifying units 421 and 422. The plurality of first and second input amplifying units 421 and 422 may correspond to a plurality of first and second transformers 411 and 412 in a one-to-one manner and may be electrically connected therewith, respectively.

The first and second input amplifying units 421 and 422 amplify input signals RFin+ and RFin− with a pre-set gain and transfer the amplified signals to the corresponding transformers 411 and 412, respectively, for impedance matching.

The impedance matching unit 410 may include the plurality of first and second transformers 411 and 412.

As shown in FIG. 2, the first and second transformers 411 and 412 may have first and second input lines 411a and 412a and first and second output lines 411b and 412b, respectively. The first and second input lines 411a and 412a receive the amplified signals from the corresponding input amplifying units 421 and 422, respectively, and the first and second output lines 411b and 412b of the first and second transformers 411 and 412 may be electromagnetically coupled with the first and second input lines 411a and 412a to match the impedance of the paths of the transferred signals. One end and the other end of each of the second input line 412a and the second output line 412b may cross each other. The configuration and operation of the first and second input lines are the same as those illustrated in FIG. 2, so a detailed description thereof will be omitted.

The second amplifying unit 430 may include a plurality of first and second output amplifying units 431 and 432.

The plurality of first and second output amplifying units 431 and 432 may correspond to the plurality of first and second transformers 411 and 412 in a one-to-one manner and may be electrically connected therewith, respectively.

The first and second output amplifying units 431 and 432 may amplify the impedance-matched signals transferred from the corresponding transformers with a pre-set gain and output the amplified signals (RFout+, RFout−). In this case, unlike the polarity of the output of the second output line 312b of the second transformer 312 illustrated in FIG. 3, the polarity of the signal output from the second output line 412b of the second transformer 412 is the same as that of the signal output from the first output line 411b of the first transformer 411, so the polarity of the signal output from the second output amplifying unit 432 is the same as that of the signal output from the first output amplifying unit 431.

In this manner, in the exemplary embodiments of the present invention, the current directions of the adjacent lines in the impedance matching circuit are made to be the same to mutually compensate for the magnetic fields according to the current directions, thereby restraining interference between the signal lines and increase the efficiency of signal transmissions.

As set forth above, according to exemplary embodiments of the invention, currents at adjacent lines are controlled to flow in the same direction to eliminate an interference between the lines, whereby a magnetic field of the output lines can be compensated for, and thus, the efficiency of a signal transmission can be increased.

While the present invention has been shown and described in connection with the exemplary embodiments, it will be apparent to those skilled in the art that modifications and variations can be made without departing from the spirit and scope of the invention as defined by the appended claims.

What is claimed is:

1. An impedance matching circuit eliminating interference between signal lines, the circuit comprising:
a first transformer including a first input line which forms a first loop by a conductor of a certain length having one end and the other end receiving a signal, and a first output line which forms a second loop by a conductor of a certain length having one end and the other end outputting a signal at the inner side of the first loop of the first input line to match the impedance of a path of an input signal according to its electromagnetic reaction with the first input line; and
a second transformer including a second input line which forms a third loop by a conductor of a certain length having one end and the other end receiving a signal, and a second output line which forms a fourth loop by a conductor of a certain length having one end and the other end outputting a signal at the inner side of the third loop of the second input line to match the impedance of a path of an input signal according to its electromagnetic reaction with the second input line,
wherein the direction of current in the first input line of the first transformer and the direction of current in the second input line of the second transformer are the opposite so that a portion of the first input line of the first transformer and a portion of the second input line of the second transformer adjacent to the portion of the first input line of the first transformer have the same current direction.

2. The impedance matching circuit of claim 1, wherein a plurality of first and second transformers are provided, wherein the plurality of first transformers are disposed in a row, and the plurality of second transformers are disposed between the first transformers.

3. The impedance matching circuit of claim 1, wherein a balanced signal is input to each of the first and second transformers.

4. A power amplifier having an impedance matching circuit eliminating interference between signal lines, the amplifier comprising:
an amplifying unit amplifying an input signal; and
an impedance matching unit including a first transformer including a first input line which forms a first loop by a conductor of a certain length having one end and the other end receiving a signal which has been amplified by the amplifying unit and a first output line which forms a second loop by a conductor of a certain length having one end and the other end outputting a signal at the inner side of the first loop of the first input line to match the impedance of a path of an input signal according to its electromagnetic reaction with the first input line, and a second transformer including a second input line which forms a third loop by a conductor of a certain length having one end and the other end receiving a signal which has been amplified by the amplifying unit and a second output line which forms a fourth loop by a conductor of a certain length having one end and the other end outputting a signal at the inner side of the third loop of the second input line to match the impedance of a path of an input signal according to its electromagnetic reaction with the second input line, wherein the direction of current in the first input line of the first transformer and the direction of current in the second input line of the second transformer are the opposite so that a portion of the first input line of the first transformer and a portion of the second input line of the second transformer adjacent to the portion of the first input line of the first transformer have the same current direction.

5. The power amplifier of claim 4, wherein a plurality of first and second transformers may be provided, wherein the plurality of first transformers are disposed in a row, and the plurality of second transformers are disposed between the first transformers.

6. The power amplifier of claim 4, a balanced signal is input to the amplifying unit.

7. The power amplifier of claim 4, wherein the amplifying unit comprises first and second input amplifying unit formed to correspond in a one-to-one manner to the first and second transformers and providing an amplified signal.

8. The power amplifier of claim 4, wherein the amplifying unit comprises a plurality of input amplifying units, wherein the plurality of input amplifying units are formed to correspond in a one-to-one manner to the plurality of first and second transformers and providing an amplified signal.

9. A power amplifier having an impedance matching circuit eliminating interference between signal lines, the amplifier comprising:
an impedance matching unit including a first transformer including a first input line which forms a first loop by a conductor of a certain length having one end and the other end receiving a signal and a first output line which forms a second loop by a conductor of a certain length having one end and the other end outputting a signal at the inner side of the first loop of the first input line to match the impedance of a path of an input signal according to its electromagnetic reaction with the first input line, and a second transformer including a second input line which forms a third loop by a conductor of a certain length having one end and the other end receiving a signal and a second output line which forms a fourth loop by a conductor of a certain length having one end and the other end outputting a signal at the inner side of the third loop of the second input line to match the impedance of a path of an input signal according to its electromagnetic reaction with the second input line, wherein the direction of current in the first input line of the first transformer and the direction of current in the second input line of the second transformer are the opposite so that a portion of the first input line of the first transformer and a portion of the second input line of the second transformer adjacent to the portion of the first input line of the first transformer have the same current direction; and
an amplifying unit amplifying a signal outputted from the impedance matching unit.

10. The power amplifier of claim 9, wherein a plurality of first and second transformers are provided, wherein the plurality of first transformers are disposed in a row, and the plurality of second transformers are disposed between the first transformers.

11. The power amplifier of claim 9, wherein a balanced signal is input to each of the first and second transformers.

12. The power amplifier of claim 9, wherein the amplifying unit comprises at least first and second output amplifying units formed to correspond in a one-to-one manner to the first and second transformers and amplifying signals from the first and second output lines with a pre-set gain.

13. The power amplifier of claim 10, wherein the amplifying unit comprises a plurality of output amplifying units, wherein the plurality of output amplifying units are formed to correspond in a one-to-one manner to the plurality of first and second transformers and amplifying an output signal with a pre-set gain.

14. A power amplifier having an impedance matching circuit eliminating interference between signal lines, the amplifier comprising:
a first amplifying unit amplifying an input signal;
an impedance matching unit including a first transformer including a first input line which forms a first loop by a conductor of a certain length having one end and the other end receiving a signal which has been amplified by the first amplifying unit and a first output line which forms second loop by a conductor of a certain length having one end and the other end outputting a signal at the inner side of the first loop of the first input line to match the impedance of a path of an input signal according to its electromagnetic reaction with the first input line, and a second transformer including a second input line which forms a third loop by a conductor of a certain length having one end and the other end receiving a signal which has been amplified by the first amplifying unit and a second output line which forms a fourth loop by a conductor of a certain length having one end and the other end outputting a signal at the inner side of the third loop of the second input line to match the impedance of a path of an input signal according to its electromagnetic reaction with the second input line, wherein the direction of current in the first input line of the first transformer and the direction of current in the second input line of the second transformer are the opposite, so that a portion of the first input line of the first transformer and a portion of the second input line of the second transformer adjacent to the portion of the first input line of the first transformer have the same current direction; and
a second amplifying unit re-amplifying a signal output from the impedance matching unit.

15. The power amplifier of claim 14, wherein a plurality of first and second transformers are provided, wherein the plurality of first transformers are disposed in a row, and the plurality of second transformers are disposed between the first transformers.

16. The power amplifier of claim 14, wherein a balanced signal is input to the first amplifying unit.

17. The power amplifier of claim 14, wherein the first amplifying unit comprises at least first and second input amplifying units formed to correspond in a one-to-one manner to the first and second transformers and providing an amplified signal.

18. The power amplifier of claim 15, wherein the first amplifying units comprises a plurality of input amplifying units, wherein the plurality of input amplifying units are formed to correspond in a one-to-one manner to the plurality of first and second transformers and providing an amplified signal.

19. The power amplifier of claim 14, wherein the second amplifying unit comprises a plurality of first and second output amplifying units formed to correspond in a one-to-one manner to the first and second transformers and amplifying signals from the first and second output lines with a pre-set gain.

20. The power amplifier of claim 15, wherein the amplifying unit comprises a plurality of output amplifying units, and the plurality of output amplifying units may be formed to correspond in a one-to-one manner to the plurality of first and second transformers and re-amplifying an output signal with a pre-set gain.
